(19) United States
(12) Patent Application Publication
(10) Pub. No.: US 2021/0071316 A1
(43) Pub. Date: Mar. 11, 2021

(54) CRYSTAL GROWTH APPARATUS

(71) Applicant: ZING SEMICONDUCTOR CORPORATION, Shanghai (CN)

(72) Inventors: Weimin Shen, Shanghai (CN); Gang Wang, Shanghai (CN)

(21) Appl. No.: 17/016,439

(22) Filed: Sep. 10, 2020

(30) Foreign Application Priority Data
Sep. 11, 2019 (CN) 201910860777.8

(51) Int. Cl. C30B 35/00; C30B 15/10; C30B 15/14

(52) U.S. Cl. CPC C30B 35/002; C30B 15/14; C30B 15/10

(57) ABSTRACT

The present invention provides a semiconductor crystal growth apparatus, which comprises a furnace body, a crucible, a pulling device, a deflector, and a magnetic field applying device. The crucible is disposed inside the furnace body for containing silicon melt. The pulling device is disposed on the top of the furnace body for pulling a silicon ingot from the silicon melt. The deflector is in a barrel shape and is disposed in the furnace body in a vertical direction, and the pulling device pulls the silicon ingot in a vertical direction and through the deflector. The magnetic field applying device is configured to apply a magnetic field to the silicon melt in the crucible, in which the distance between the bottom of the deflector and the liquid level of the silicon melt in the direction of the magnetic field is less than that between the bottom of the deflector and the silicon melt in the direction perpendicular to the direction of the magnetic field.

### CROSS-REFERENCE TO RELATED APPLICATIONS

This application claims priority to P.R.C. Patent Application No. 201910860777.8 titled “Crystal growth apparatus” filed on Sep. 11, 2019, with the State Intellectual Property Office of the People's Republic of China (SIPO).

### TECHNICAL FIELD

The present disclosure relates to a crystal growth technology, specifically to a crystal growth apparatus.

### BACKGROUND

With the rapid development of integrated circuit (IC) industry, component manufacturers have put forward stricter requirements for IC grade single crystalline materials, and large diameter single crystalline is a necessary substrate material for preparing components. The Czochralski Process (CZ) method is the most important method for growing single crystal from melt. The specific method is to heat and melt the raw materials constituting the crystal in a quartz crucible, then connect the seed crystal on the surface of the melt to pull the melt. Under controlled conditions, the seed crystal and the melt constantly is carried out rearranging of atom or molecule at the interface, and the crystal is gradually solidified as the temperature is lowered to grow a crystal.

During the growth of silicon crystal, a part of the quartz crucible (SiO₂) that is in contact with the silicon melt is dissolved into the silicon melt, and diffused and mixed in the form of SiO gas on the surface of the silicon liquid into argon gas and drawn out of the furnace body by a vacuum pump. When this mixed gas passes through the graphite heater, it reacts with the graphite on the surface, causing the graphite of the heater to be continuously eroded, such that the thickness and the width are gradually decreased, the resistance is gradually increased, and the unstable heating effect leads to unstable quality of crystal growth.

### SUMMARY

A series of simplified forms of concepts are introduced in the summary section, which will be explained in further detail in the detailed description section. The summary of the present invention does not mean trying to define the key features and necessary technical features of the claimed technical solution, let alone trying to determine the protection scope of the claimed technical solution.

The present invention provides a crystal growth apparatus, comprises:
a crucible, which is configured to contain a melt for a crystal growth;
a heater, which is disposed around the crucible and configured to heat the crucible;
a deflector sleeve, which is disposed between the heater and the crucible; and
an auxiliary structure, which is connected with the deflector sleeve to surround a top and a lateral surface of the heater.

In accordance with some embodiments, a lower surface of the deflector sleeve is lower than a lower surface of the heater.

In accordance with some embodiments, a gap between adjacent surfaces of the deflector sleeve and the heater is larger than 10 mm, and a gap between adjacent surfaces of the deflector sleeve and the crucible is larger than 10 mm.

In accordance with some embodiments, a thickness of the deflector sleeve is between 2 mm-20 mm.

In accordance with some embodiments, the crystal growth apparatus further comprises a furnace body and a thermal isolation structure disposed in the furnace body, wherein the auxiliary structure covers the thermal isolation structure.

In accordance with some embodiments, the auxiliary structure and the deflector sleeve are designed as a single part.

In accordance with some embodiments, the deflect sleeve is designed as a single part or composed of multi segments.

In accordance with some embodiments, a shape of the deflector sleeve is cylinder or a conical cylinder, or a combination of a cylinder and a conical cylinder.

In accordance with some embodiments, the material of the deflector sleeve comprises graphite or carbon/carbon composite material.

In accordance with some embodiments, the crystal growth apparatus further comprises an exhaust device, disposed on a bottom of the crystal growth apparatus, wherein a distance from a center of the exhaust device to a center of the furnace body is smaller than a radius of the deflector sleeve.

In accordance with some embodiments, the crucible comprises a graphite crucible and a quartz crucible, the melt comprises a silicon melt, and the heater includes a graphite heater.

According to the crystal growth apparatus provided in the present invention, by arranging a deflector sleeve between the heater and the crucible, and setting the deflector sleeve and the auxiliary structure to be connected and combined to surround the top and the lateral surface of the heater, the erosion of the surface of the heater by SiO vapor can be avoid, the service life of the heater and improve the stability of the crystal growth quality.

### BRIEF DESCRIPTION OF THE DRAWINGS

Exemplary embodiments will be more readily understood from the following detailed description when read in conjunction with the appended drawings, in which:

FIG. 1 is a schematic diagram of a crystal growth apparatus in the prior art.

FIG. 2 is a schematic diagram of a crystal growth apparatus according to one embodiment of the present invention.

### DETAILED DESCRIPTION

In the following description, numerous specific details are given to provide a more thorough understanding of the present invention. However, it will be apparent to one skilled in the art that the present invention may be practiced without one or more of these details. In other examples, in order to avoid confusion with the present invention, some technical features known in the art are not described.

For a thorough understanding of the present invention, a detailed description will be provided in the following description to illustrate the method according to the present invention. Obviously, the implementation of the present invention is not limited to the specific details familiar to those skilled in the semiconductor field. The preferred embodiments of the present invention are described in detail below. However, in addition to these detailed descriptions, the present invention may have other embodiments.

It should be noted that terminology used herein is for the purpose of describing particular embodiments only and is not intended to limit the exemplary embodiments according to the present invention. As used herein, the singular forms are intended to comprise the plural forms as well, unless the context clearly indicates otherwise. In addition, it should also be understood that when the terms “including” and/or “including” are used in this specification, they indicate the presence of stated features, integers, steps, operations, elements and/or components, but do not exclude the presence or Add one or more other features, wholes, steps, operations, elements, components, and/or combinations thereof.

Now, exemplary embodiments according to the present invention will be described in more detail with reference to the accompanying drawings. These exemplary embodiments may, however, be embodied in many different forms and should not be construed as limited to the embodiments set forth herein. It should be understood that these embodiments are provided so that this disclosure will be thorough and complete, and will fully convey the concept of the exemplary embodiments to those skilled in the art. In the drawings, the thicknesses of layers and regions are exaggerated for the sake of clarity, and the same elements are denoted by the same reference numerals, and their descriptions will be omitted.

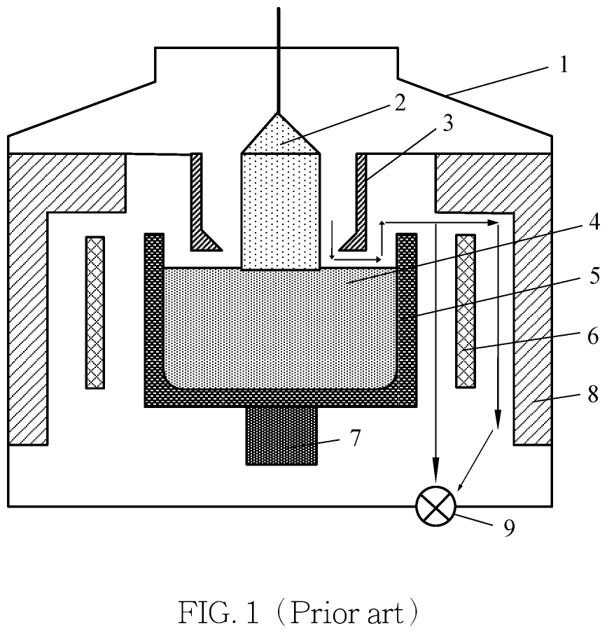

Referring to FIG. 1, FIG. 1 is a schematic structural diagram of a crystal growth apparatus. During the CZ crystal growth, due to an inner wall of the quartz crucible in contact with the silicon melt is dissolved and diffused, a large amount of oxygen atoms are dissolved into the silicon melt. Most of the oxygen freely escapes from the surface of the silicon melt into argon gas in the form of SiO vapor. The SiO vapor reacts with graphite as it passes through the high-temperature graphite surface of the heater 6 as follows:

SiO (gas)+2C (Solid)=CO (gas)+SiC (Solid) (Formula 1)

In addition, due to the presence of the plate-shaped fixing structure, most of the SiO vapor is prevented from diffusing to the upper part of the furnace body 1. Further, since the vacuum pump 9 is provided at the bottom of the furnace body 1, the SiO vapor is caused to move below the furnace body 1, so a large amount of SiO vapor will pass through the heater 6 and react as abovementioned with the high-temperature graphite surface thereof.

As the above reaction occurs, CO gas and argon gas are discharged from the furnace body 1 through the vacuum pump 9, and SiC is deposited on the graphite surface, such that the graphite elements in the crystal growth apparatus are continuously eroded by the reaction, especially the high-temperature graphite surface of the heater 6. After a certain time or number of uses, the thickness and the width of the graphite on the surface of the heater 6 will be decreased, and the energization resistance of the heater 6 is gradually increased. At the same time, the heating range and the heating effect of the heater 6 also change, resulting in unstable quality of crystal growth.

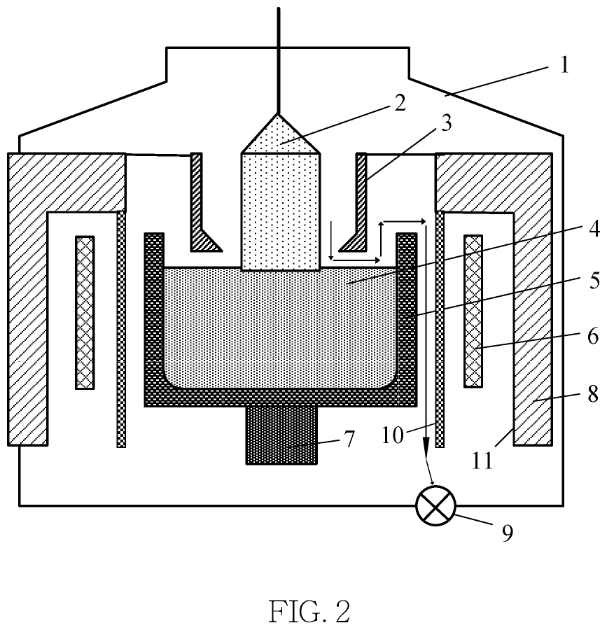

Regarding above mentioned problems, the present invention provides a crystal growth apparatus as shown in FIG. 2, which may comprise:
a crucible 5, which is configured to contain a melt 4 for a crystal growth;
a heater 6, which is disposed around the crucible 5 and configured to heat the crucible 5;
a reflector sleeve 10, which is disposed between the heater 6 and the crucible 5; and
an auxiliary structure 11, which is connected with the deflector sleeve 10 to surround a top and a lateral surface of the heater.

Referring to FIG. 2, FIG. 2 is a schematic structural diagram of the crystal growth apparatus. The crystal growth apparatus may comprise a furnace body 1, a crucible 5, a heater 6, and a reflection shield 3. The crucible 5 may be disposed in the furnace body 1, and the heater 6 may be disposed around the crucible 5. The crucible 5 may contain a melt 4, a crystal 2 may be grown on the melt 4, and the reflection shield 3 may be disposed on the top of the crucible 5 and surrounding the crystal 2. According to one embodiment, the melt 4 in the crucible 5 may be silicon melt, and the grown crystal 2 may be a single silicon ingot.

For example, the furnace body 1 is a stainless steel cavity, and the inside of the furnace body 1 is vacuum or filled with protective gas.

For example, the crucible 5 is made of high-temperature and corrosion-resistant material, and the crucible 5 contains the melt 4 for crystal growth. In one embodiment, the crucible 5 may include a quartz crucible and/or a graphite crucible, and the quartz crucible is placed in the graphite crucible. The crucible 5 contains silicon material, such as polycrystalline silicon. The silicon material is heated in the crucible 5 to a silicon melt for growing a single crystalline ingot. Specifically, the seed crystal is immersed in the silicon melt, and the seed crystal is driven to rotate and slowly pulled by a seed crystal axis, so that silicon atoms are grown into a crystalline ingot along the seed crystal. The seed crystal is formed by cutting or drilling a single crystalline with a certain crystal orientation, and common crystal orientations are <100>, <111>, <110>, etc. The seed crystal is generally a cylinder.

For example, a heater 6 is provided on a periphery of the crucible 5, and the heater 6 is a graphite heater, which may be disposed on the lateral surface of the crucible 5, and configured to heat the crucible 5. Further, the heater 6 may be comprise one or more heaters arranged around the crucible 5 to make the crucible 5 have a uniform thermal field distribution.

For example, the furnace body 1 is further provided with a reflection shield 3, which is located above the crucible 5, and is disposed outside and around the crystal 2 to avoid the heat of the melt 4 being transferred in the form of heat radiation, etc. into the furnace body 1, causing heat loss.

Further, the crystal growth apparatus may further comprise a crucible lifting mechanism 7, which is configured to support and rotate the crucible shaft to achieve lifting and lowering of the crucible 5.

Further, the crystal growth device may further comprise a thermal isolation structure 8, which is disposed on the inner wall of the furnace body 1 to prevent heat loss and realize the thermal insulation of the furnace body 1. The thermal isolation structure 8 is located above and outside the heater 6.

Further, the crystal growth apparatus may further comprise a vacuum pump 9, which is configured to extract the gas in the furnace body 1. The vacuum pump 9 is provided at the bottom of the furnace body 1 to discharge the gas in the furnace body 1 from the lower side of the furnace body 1.

Comparing the vacuum pump 9 disposed at the bottom of the furnace body 1 and exhausted on the lower side with the vacuum pump 9 disposed in the upper part of the furnace body 1 and exhausted on the upper side, the exhaust on the upper side leads to greater heat loss in the upper part of the furnace body 1, and the temperature is uneven in the circumferential direction, which leads to a decrease in the crystal growth yield. The exhaust on the lower side has a smaller effect on the temperature of the area around the crystal growth, ensuring good growth of the crystal.

As shown in FIG. 2, the reflection shield 3 is connected to the thermal isolation structure 8 by a fixing structure to fix the reflection shield 3 above the crucible 5. The fixing structure is usually a plate-like structure, therefore, the existence of the fixing structure can avoid the gas circulation above and below the fixing structure.

In one embodiment, the auxiliary structure 11 may comprise a part of the original structure in the crystal growth apparatus, such as a part of the thermal isolation structure 8, which is connected to the reflector sleeve 10 to form a cover with only an opening at the bottom, surrounding the top and the lateral surface of the heater 6. In one embodiment, as shown in FIG. 2, the auxiliary structure 11 cover above the thermal isolation structure 8. The thermal isolation structure 8 is originally located above and outside the heater 6, and after it is connected to the deflector sleeve 10, the deflector sleeve 10 is connected to the auxiliary structure 11 covering the thermal isolation structure 8, so as to form a cover structure surrounding the top and the lateral surface of the heater 6, such that the bottom of the heater 6 is exposed.

In another embodiment, the auxiliary structure 11 is a structure specifically designed for the crystal growth apparatus of the present invention, which is designed integrally with the deflector sleeve 10 or connected and combined with the deflector sleeve 10 to form a cover with only an opening at the bottom surrounding the top and lateral surface of the heater 6.

For example, the length of the deflector sleeve 10 should at least ensure that the heating area of the heater 6 (e.g. the portion of the heater 6 through which the current passes) is above the bottom of the deflector sleeve 10 to avoid the reaction of the SiO vapor and the high-temperature graphite surface of the heater 6. Preferably, the lower surface of the deflector sleeve 10 is lower than the lower surface of the heater 6.

Further, the thickness range of the deflector sleeve 10 is preferably set to be between 2 mm-20 mm. By controlling the thickness range of the deflector sleeve 10, the deflector sleeve 10 can achieve the effect of blocking SiO vapor without affecting the heat radiation of the heater 6 to the crucible 5.

By forming a cover that surrounds the top and lateral surface of the heater 6, the heater 6 can be separated from the airflow channel. As shown in FIG. 2, under the action of the vacuum pump 9, the SiO vapor flows from the top of the crucible 5 toward the bottom of the furnace body 1 and is discharged. Under the isolation effect of the deflector sleeve 10, the SiO vapor does not pass through the heater 6, so as to avoid the reaction of SiO vapor and high-temperature graphite surface of the heater 6.

By reducing the erosion loss of the heater 6, the service life of the heater 6 is extended, specifically, the number of times the heater 6 is used is extended from 30 times to more than 80 times. Similarly, due to the slower erosion loss of the heater 6, the frequency of adjustment of process parameters during the crystal growth process is reduced. Specifically, the adjustment from each batch to be extended to every 5 batches.

Alternatively, only the top and lateral surface of the heater 6 are surrounded, and the bottom of the heater 6 is not surrounded by the cover composed of the deflector sleeve 10 and the auxiliary structure 11 described above.

Comparing the bottom of the heater 6 exposed by arranging an opening under the cover with the heater 6 completely surround by the cover, the erosion of the surface of the heater 6 by SiO vapor is not significantly different, and the bottom opening is conducive to the cleaning, inspection and maintenance of the equipment, while the structure is simple, easy to process, and the cost is reduced.

In one embodiment, the cover formed by the deflector sleeve 10 and the auxiliary structure 11 surrounds the heater 6, but there is a certain distance between the cover and the heater 6. Preferably, a gap between the adjacent surfaces of the deflector sleeve 10 and the heater 6 is greater than 10 mm, and a gap between adjacent surfaces of the deflector sleeve 10 and the crucible 5 is greater than 10 mm. Specifically, a distance between an outer surface on the side of the deflector sleeve 10 away from the crucible 5 and an inner surface on the side of the heater 6 close to the crucible 5 is greater than 10 mm. A distance between the inner surface on the side of the deflector sleeve 10 close to the crucible 5 and an outer surface of the crucible 5 is greater than 10 mm.

For example, the shape of the deflector sleeve 10 is a cylinder or a conical cylinder, or a combination of a cylinder and a conical cylinder. Further, the distance from the center of the exhaust device to the center of the furnace body 1 is smaller than the radius of the deflector sleeve 10. In one embodiment, the distance from the vacuum pump 9 to the center of the bottom of the furnace body 1 is smaller than the radius of the deflector sleeve 10, so that the SiO vapor is discharged out of the furnace body 1 along the inner surface of the deflector sleeve 10 to avoid contact of the SiO vapor with the heater 6.

For example, the material of the deflector sleeve 10 includes graphite or carbon/carbon composite material. In one embodiment, the material of the deflector sleeve 10 is high-purity graphite. In another embodiment, the material of the deflector sleeve 10 is a carbon/carbon composite material. The carbon/carbon composite material is a carbon matrix composite material reinforced with carbon fiber and its fabric, which has low density, high strength and high specific modulus, high thermal conductivity, low expansion coefficient, good friction performance, good thermal shock resistance, high dimensional stability and other advantages.

The deflector sleeve 10 made of graphite or carbon/carbon composite material with high temperature resistance and good thermal insulation effect not only enables the deflector sleeve 10 to achieve the function of gas guide, but also enhances the insulation around the crucible 5. As a result, the quality of crystal growth is more stable.

According to the crystal growth apparatus provided in the present invention, a deflector sleeve is provided between the heater and the crucible, and the deflector sleeve and the auxiliary structure can be connected and combined to surround the top and lateral surface of the heater to avoid the erosion of the heater surface by SiO vapor, such that the service life of the heater is extended, and the stability of the crystal growth quality is improved.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A crystal growth apparatus, comprising:
a crucible, configured to contain a melt for a crystal growth;
a heater, disposed around the crucible and configured to heat the crucible;
a deflector sleeve, disposed between the heater and the crucible; and
an auxiliary structure, connected with the deflector sleeve to surround a top and a lateral surface of the heater.

2. The apparatus according to claim 1, wherein a lower surface of the deflector sleeve is lower than a lower surface of the heater.

3. The apparatus according to claim 1, wherein a gap between adjacent surfaces of the deflector sleeve and the heater is larger than 10 mm, and a gap between adjacent surfaces of the deflector sleeve and the crucible is larger than 10 mm.

4. The apparatus according to claim 1, wherein a thickness of the deflector sleeve is between 2 mm-20 mm.

5. The apparatus according to claim 1, further comprising a furnace body and a thermal isolation structure disposed in the furnace body, wherein the auxiliary structure covers the thermal isolation structure.

6. The apparatus according of claim 1, wherein the auxiliary structure and the deflector sleeve are designed as a single part.

7. The apparatus according to claim 1, wherein the deflect sleeve is designed as a single part or composed of multi segments.

8. The apparatus according to claim 1, wherein a shape of the deflector sleeve is cylinder or a conical cylinder, or a combination of a cylinder and a conical cylinder.

9. The apparatus according to claim 1, wherein the material of the deflector sleeve comprises graphite or carbon/carbon composite material.

10. The apparatus according to claim 5, further comprising an exhaust device, disposed on a bottom of the crystal growth apparatus, wherein a distance from a center of the exhaust device to a center of the furnace body is smaller than a radius of the deflector sleeve.

11. The apparatus according to claim 1, wherein the crucible comprises a graphite crucible and a quartz crucible, the melt comprises a silicon melt, and the heater comprises a graphite heater.
